(19) United States
(12) Patent Application Publication
(10) Pub. No.: US 2021/0262115 A1
(43) Pub. Date: Aug. 26, 2021

(54) METHOD AND DEVICE FOR CONTROLLING CONSTANT-DIAMETER GROWTH OF MONOCRYSTAL SILICON AND STORAGE MEDIUM

(71) Applicant: LONGI GREEN ENERGY TECHNOLOGY CO., LTD., Xi'an (CN)

(72) Inventors: Zhengyuan WANG, Xi'an (CN); Qiao LI, Xi'an (CN); Zhanjun XU, Xi'an (CN)

(73) Assignee: LONGI GREEN ENERGY TECHNOLOGY CO., LTD., Xi'an (CN)

(21) Appl. No.: 17/256,327

(22) PCT Filed: Nov. 11, 2019
(86) PCT No.: PCT/CN2019/117202

§ 371 Date: Dec. 28, 2020

(30) Foreign Application Priority Data
Dec. 3, 2018 (CN) 201811465277.6

(51) Int. Cl. C30B 15/22; C30B 29/06; G06F 17/18

(52) U.S. Cl. CPC C30B 15/22; G06F 17/18; C30B 29/06

(57) ABSTRACT

A method and device for controlling constant-diameter growth of monocrystalline silicon and a storage medium, relating to the technical field of crystal fabrication, which can automatically adjust the controlling level of the crystal constant-diameter growth, to in turn control the crystal diameter better. The particular technical solution includes: acquiring PID initial values of an i-th cycle period; correcting the PID initial values of the i-th cycle period, and obtaining PID corrected values of the i-th cycle period; and according to the PID corrected values of the i-th cycle period, controlling a crystal growth diameter of the i-th cycle period. The present application is used to control constant-diameter growth of monocrystalline silicon.

The present application claims the priority of the Chinese patent application filed on Dec. 3, 2018 before the Chinese Patent Office with the application number of 201811465277.6 and the title of “METHOD AND DEVICE FOR CONTROLLING CONSTANT-DIAMETER GROWTH OF MONOCRYSTAL SILICON AND STORAGE MEDIUM”, which is incorporated herein in its entirety by reference.

### TECHNICAL FIELD

The present disclosure relates to the technical field of crystal fabrication, and particularly relates to a method and device for controlling constant-diameter growth of monocrystalline silicon and a storage medium.

### BACKGROUND

The fabrication of czochralski silicon comprises placing the polycrystalline silicon material in to a quartz crucible, heating to melt into a silicon melt, and then performing the steps of temperature regulating, seeding, shouldering, shoulder circuiting, diameter equalization, closing and so on, to finally fabricate the monocrystalline silicon rod. In the process of constant-diameter growth of monocrystalline silicon, in conventional controlling modes, the controlling level during the entire constant-diameter growth is constant. However, in the earlier stage of the constant-diameter growth, the fluctuation of the diameter deviation of the crystal head is large, which requires a higher controlling level, but in the middle and later stages of the constant-diameter growth, the diameter fluctuation of the crystal decreases, which requires a lower controlling level. Therefore, the conventional controlling modes cannot satisfy the requirements on the controlling.

### SUMMARY

The above description is merely a summary of the technical solutions of the present application. In order to more clearly know the elements of the present application to enable the implementation according to the contents of the description, and in order to make one of the above and other purposes, features and advantages of the present application more apparent and understandable, particular embodiments of the present application will be provided below.

The embodiments of the present disclosure provide a method and device for controlling constant-diameter growth of monocrystalline silicon and a storage medium, which can automatically adjust the controlling level of the crystal constant-diameter growth, to in turn control the crystal diameter better. The technical solutions are as follows:

According to a first aspect of the embodiments of the present disclosure, there is provided a method for controlling constant-diameter growth of monocrystalline silicon, wherein the method comprises:

acquiring PID initial values of an i-th cycle period, wherein the PID initial values include an initial value of a proportion component P, an initial value of an integration component I and an initial value of a differentiation component D, and i≥1;

correcting the PID initial values of the i-th cycle period, and obtaining PID corrected values of the i-th cycle period, wherein the PID corrected values include a corrected value of the proportion component P, a corrected value of the integration component I and a corrected value of the differentiation component D; and

according to the PID corrected values of the i-th cycle period, controlling a crystal growth diameter of the i-th cycle period.

The method, by correcting in real time the PID values of each of the cycle periods in the process of the crystal constant-diameter growth, automatically adjusts the controlling level of the crystal constant-diameter growth, to in turn control the crystal diameter better.

In an embodiment, the method further comprises: the step of acquiring the PID initial values of the i-th cycle period comprises:

determining PID corrected values of an (i−1)-th cycle period to be the PID initial values of the i-th cycle period.

In an embodiment, the step of correcting the PID initial values of the i-th cycle period, and obtaining the PID corrected values of the i-th cycle period comprises:

setting, in the i-th cycle period, a target threshold of the proportion component P and a corresponding adaptive parameter, a target threshold of the integration component I and a corresponding adaptive parameter and a target threshold of the differentiation component D and a corresponding adaptive parameter;

according to the target threshold of the proportion component P and the corresponding adaptive parameter, calculating to obtain the corrected value of the proportion component P;

according to the target threshold of the integration component I and the corresponding adaptive parameter, calculating to obtain the corrected value of the integration component I; and

according to the target threshold of the differentiation component D and the corresponding adaptive parameter, calculating to obtain the corrected value of the differentiation component D.

In an embodiment, the step of setting the target threshold of the proportion component P of the i-th cycle period and the corresponding adaptive parameter comprises:

acquiring a diameter difference of the i-th cycle period, wherein the diameter difference is a difference between a target crystal diameter and a real-time crystal diameter;

setting 1/100-½ of an absolute value of the diameter difference of the i-th cycle period to be the target threshold of the proportion component P;

setting 1/1000- 1/10000 of the initial value of the proportion component P of the i-th cycle period to be a first adaptive parameter of the proportion component P; and

setting 1/10000- 1/100000 of the initial value of the proportion component P of the i-th cycle period to be a second adaptive parameter of the proportion component P.

In an embodiment, the step of acquiring the diameter difference of the i-th cycle period comprises:

collecting an initial crystal diameter of the i-th cycle period;

setting the target crystal diameter of the i-th cycle period; and

according to the crystal growth diameter of the i-th cycle period and the target crystal diameter of the i-th cycle period, calculating to obtain the diameter difference of the i-th cycle period.

In an embodiment, the step of setting the target threshold of the integration component I of the i-th cycle period and the corresponding adaptive parameter comprises:

acquiring diameter differences of the i-th cycle period and M cycle periods preceding the i-th cycle period, wherein M≤i−1

calculating an average value of all of the diameter differences of the M+1 cycle periods;

setting 1/100-½ of the average value to be the target threshold of the integration component I;

setting 1/1000- 1/10000 of the initial value of the integration component I of the i-th cycle period to be a first adaptive parameter of the integration component I; and

setting 1/10000- 1/100000 of the initial value of the integration component I of the i-th cycle period to be a second adaptive parameter of the integration component I.

In an embodiment, the step of setting the target threshold of the differentiation component D of the i-th cycle period and the corresponding adaptive parameter comprises:

acquiring diameter differences of the i-th cycle period and M cycle periods preceding the i-th cycle period, wherein M≤i−1;

calculating a standard deviation of all of the diameter differences of the M+1 cycle periods;

setting 1/100-½ of the standard deviation to be the target threshold of the differentiation component D;

setting 1/1000- 1/10000 of the initial value of the differentiation component D of the i-th cycle period to be a first adaptive parameter of the differentiation component D; and

setting 1/10000- 1/100000 of the initial value of the differentiation component D of the i-th cycle period to be a second adaptive parameter of the differentiation component D.

In an embodiment, the step of, according to the target threshold of the proportion component P and the corresponding adaptive parameter, calculating to obtain the corrected value of the proportion component P comprises:

according to the diameter difference of the i-th cycle period and the target threshold of the proportion component P and the corresponding adaptive parameter, by using a first formula, calculating to obtain the corrected value of the proportion component P, wherein the first formula comprises:

Pᵢ_{_{corrected}}=P₍ᵢ₋₁₎_{_{corrected}}+(|Dᵢ_{ₑᵣᵣ}|−Pᵢ_{_{threshold}})×αᵢ_{ₐ₁}+∫₀^{t}(|Dᵢ_{ₑᵣᵣ}|−Pᵢ_{_{threshold}})×βᵢ_{ₐ₁}

wherein Pᵢ_{_{corrected}} represents the corrected value of the proportion component P of the i-th cycle period, P₍ᵢ₋₁₎_{_{corrected}} represents the initial value of the proportion component P of the i-th cycle period, Dᵢ_{ₑᵣᵣ} represents the diameter difference of the i-th cycle period, αᵢ_{ₐ₁} represents the first adaptive parameter of the proportion component P of the i-th cycle period, βᵢ_{ₐ₁} represents the second adaptive parameter of the proportion component P of the i-th cycle period, Pᵢ_{_{threshold}} represents the target threshold of the proportion component P of the i-th cycle period, and t represents the duration of the cycle period.

In an embodiment, the step of, according to the diameter difference and the target threshold of the integration component I and the corresponding adaptive parameter, calculating to obtain the corrected value of the integration component I comprises:

according to the diameter difference and the target threshold of the integration component I and the corresponding adaptive parameter, by using a second formula, calculating to obtain the corrected value of the integration component I, wherein the second formula comprises:

Iᵢ_{_{corrected}}=I₍ᵢ₋₁₎_{_{corrected}}+(|̅D̅ⱼ̅_̅{̅ₑ̅ᵣ̅ᵣ̅}̅|̅−Iᵢ_{_{threshold}})×αᵢ_{ₐ₂}+∫₀^{t}(|̅D̅ⱼ̅_̅{̅ₑ̅ᵣ̅ᵣ̅}̅|̅−Iᵢ_{_{threshold}})×βᵢ_{ₐ₂}

wherein Iᵢ_{_{corrected}} represents the corrected value of the integration component I of the i-th cycle period, I₍ᵢ₋₁₎_{_{corrected}} represents the initial value of the integration component I of the i-th cycle period, Dⱼ_{ₑᵣᵣ} represents the diameter difference of the i-th cycle period in M+1 cycle periods, |D̅ⱼ̅_̅{̅ₑ̅ᵣ̅ᵣ̅}̅| represents the average value of the absolute values of all of the diameter differences in the M+1 cycle periods, αᵢ_{ₐ₂} represents the first adaptive parameter of the integration component I of the i-th cycle period, βᵢ_{ₐ₂} represents the second adaptive parameter of the integration component I of the i-th cycle period, t represents the target threshold of the integration component I of the i-th cycle period, and t represents the duration of the cycle period.

In an embodiment, the step of, according to the target threshold of the differentiation component D and the corresponding adaptive parameter, calculating to obtain the corrected value of the differentiation component D comprises:

according to the diameter difference and the target threshold of the differentiation component D and the corresponding adaptive parameter, by using a third formula, calculating to obtain the corrected value of the differentiation component D, wherein the third formula comprises:

$${D}_{{i}_{corrected}} = {D}_{{( i - 1 )}_{corrected}} + ( \sqrt{\frac{1}{M + 1} \sum {( \vert {D}_{{j}_{err}} \vert )}^{2}} - {D}_{{i}_{threshold}} ) \times {α}_{{i}_{a 3}} + {\int }_{0}^{t} ( \sqrt{\frac{1}{M + 1} \sum {( \vert {D}_{{j}_{err}} \vert )}^{2}} - {D}_{{i}_{threshold}} ) \times {β}_{{i}_{a 3}}$$

wherein Dᵢ_{_{corrected}} represents the corrected value of the differentiation component D of the i-th cycle period, D₍ᵢ₋₁₎_{_{corrected}} represents the initial value of the differentiation component D of the i-th cycle period, Dⱼ_{ₑᵣᵣ} represents the diameter difference of the i-th cycle period in M+1 cycle periods, Dᵢ_{_{threshold}} represents the target threshold of the differentiation component D of the i-th cycle period, αᵢ_{ₐ₃} represents the first adaptive parameter of the differentiation component D of the i-th cycle period, βᵢ_{ₐ₃} represents the second adaptive parameter of the differentiation component D of the i-th cycle period, and t represents the duration of the cycle period.

According to a second aspect of the embodiments of the present disclosure, there is provided an apparatus for controlling constant-diameter growth of monocrystalline silicon, comprising: an acquiring module, a correcting module and a controlling module;

the acquiring module is configured for acquiring PID initial values of an i-th cycle period, wherein the PID initial values include an initial value of a proportion component P, an initial value of an integration component I and an initial value of a differentiation component D, and i≥1;

the correcting module is configured for correcting the PID initial values of the i-th cycle period, and obtaining PID corrected values of the i-th cycle period, wherein the PID corrected values include a corrected value of the proportion component P, a corrected value of the integration component I and a corrected value of the differentiation component D; and

the controlling module is configured for, according to the PID corrected values of the i-th cycle period, controlling a crystal growth diameter of the i-th cycle period.

In an embodiment, the acquiring module is configured for determining PID corrected values of an (i−1)-th cycle period to be the PID initial values of the i-th cycle period.

In an embodiment, the correcting module comprises: a setting module and a calculating module;

the setting module is configured for setting, in the i-th cycle period, a target threshold of the proportion component P and a corresponding adaptive parameter, a target threshold of the integration component I and a corresponding adaptive parameter and a target threshold of the differentiation component D and a corresponding adaptive parameter;

the calculating module is configured for, according to the target threshold of the proportion component P and the corresponding adaptive parameter, calculating to obtain the corrected value of the proportion component P;

the calculating module is configured for, according to the target threshold of the integration component I and the corresponding adaptive parameter, calculating to obtain the corrected value of the integration component I; and

the calculating module is configured for, according to the target threshold of the differentiation component D and the corresponding adaptive parameter, calculating to obtain the corrected value of the differentiation component D.

In an embodiment, the setting module comprises: an acquiring module and a setting module;

the acquiring module is configured for acquiring a diameter difference of the i-th cycle period;

the setting module is configured for setting 1/100-½ of an absolute value of the diameter difference of the i-th cycle period to be the target threshold of the proportion component P;

the setting module is configured for setting 1/1000- 1/10000 of the initial value of the proportion component P of the i-th cycle period to be a first adaptive parameter of the proportion component P; and

the setting module is configured for setting 1/10000- 1/100000 of the initial value of the proportion component P of the i-th cycle period to be a second adaptive parameter of the proportion component P.

In an embodiment, the setting module further comprises a calculating module;

the acquiring module is configured for acquiring diameter differences of the i-th cycle period and M cycle periods preceding the i-th cycle period, wherein M≥i−1;

the calculating module is configured for calculating an average value of all of the diameter differences of the M+1 cycle periods;

the setting module is configured for setting 1/100-½ of the average value to be the target threshold of the integration component I;

the setting module is configured for setting 1/1000- 1/10000 of the initial value of the integration component I of the i-th cycle period to be a first adaptive parameter of the integration component I; and

the setting module is configured for setting 1/10000- 1/100000 of the initial value of the integration component I of the i-th cycle period to be a second adaptive parameter of the integration component I.

In an embodiment, the acquiring module is configured for acquiring diameter differences of the i-th cycle period and M cycle periods preceding the i-th cycle period, wherein M≤i−1;

the calculating module is configured for calculating a standard deviation of all of the diameter differences of the M+1 cycle periods;

the setting module is configured for setting 1/100-½ of the standard deviation to be the target threshold of the differentiation component D;

the setting module is configured for setting 1/1000- 1/10000 of the initial value of the differentiation component D of the i-th cycle period to be a first adaptive parameter of the differentiation component D; and

the setting module is configured for setting 1/10000- 1/100000 of the initial value of the differentiation component D of the i-th cycle period to be a second adaptive parameter of the differentiation component D.

In an embodiment, the calculating module is configured for, according to the diameter difference of the i-th cycle period and the target threshold of the proportion component P and the corresponding adaptive parameter, by using a first formula, calculating to obtain the corrected value of the proportion component P, wherein the first formula comprises:

Pᵢ_{_{corrected}}=P₍ᵢ₋₁₎_{_{corrected}}+(|Dᵢ_{ₑᵣᵣ}||−Pᵢ_{_{threshold}})×αᵢ_{ₐ₁}+∫₀^{t}(|Dᵢ_{ₑᵣᵣ}|−Pᵢ_{_{threshold}})×βᵢ_{ₐ₁}

wherein Pᵢ_{_{corrected}} represents the corrected value of the proportion component P of the i-th cycle period, P₍ᵢ₋₁₎_{_{corrected}} represents the initial value of the proportion component P of the i-th cycle period, D₁_{ₑᵣᵣ} represents the diameter difference of the i-th cycle period, αᵢ_{ₐ₁} represents the first adaptive parameter of the proportion component P of the i-th cycle period, βᵢ_{ₐ₁} represents the second adaptive parameter of the proportion component P of the i-th cycle period, P represents the target threshold of the proportion component P of the i-th cycle period, and t represents the duration of the cycle period.

In an embodiment, the calculating module is configured for, according to the diameter difference and the target threshold of the integration component I and the corresponding adaptive parameter, by using a second formula, calculating to obtain the corrected value of the integration component I, wherein the second formula comprises:

Iᵢ_{_{corrected}}=I₍ᵢ₋₁₎_{_{corrected}}+(|̅D̅ⱼ̅_̅{̅ₑ̅ᵣ̅ᵣ̅}̅|̅−Iᵢ_{_{threshold}})×αᵢ_{ₐ₂}+∫₀^{t}(|̅D̅ⱼ̅_̅{̅ₑ̅ᵣ̅ᵣ̅}̅|̅|−Iᵢ_{_{threshold}})×βᵢ_{ₐ₁}

wherein Pᵢ_{_{corrected}} represents the corrected value of the integration component I of the i-th cycle period, P₍ᵢ₋₁₎_{_{corrected}} represents the initial value of the integration component I of the i-th cycle period, Dᵢ_{ₑᵣᵣ} represents the diameter difference of the i-th cycle period in M+1 cycle periods, |D̅ⱼ̅_̅{̅ₑ̅ᵣ̅ᵣ̅}̅| represents the average value of the absolute values of all of the diameter differences in the M+1 cycle periods, αᵢ_{ₐ₂} represents the first adaptive parameter of the integration component I of the i-th cycle period, βᵢ_{ₐ₂} represents the second adaptive parameter of the integration component I of the i-th cycle period, Iᵢ_{_{threshold}} represents the target threshold of the integration component I of the i-th cycle period, and t represents the duration of the cycle period.

In an embodiment, the calculating module is configured for, according to the diameter difference and the target threshold of the differentiation component D and the corresponding adaptive parameter, by using a third formula, calculating to obtain the corrected value of the differentiation component D, wherein the third formula comprises:

$${D}_{{i}_{corrected}} = {D}_{{( i - 1 )}_{corrected}} + ( \sqrt{\frac{1}{M + 1} \sum {( \vert {D}_{{j}_{err}} \vert )}^{2}} - {D}_{{i}_{threshold}} ) \times {α}_{{i}_{a 3}} + {\int }_{0}^{t} ( \sqrt{\frac{1}{M + 1} \sum {( \vert {D}_{{j}_{err}} \vert )}^{2}} - {D}_{{i}_{threshold}} ) \times {β}_{{i}_{a 3}}$$

wherein Dᵢ_{_{corrected}} represents the corrected value of the differentiation component D of the i-th cycle period, D₍ᵢ₋₁₎_{_{corrected}} represents the initial value of the differentiation component D of the i-th cycle period, Dⱼ_{ₑᵣᵣ} represents the diameter difference of the i-th cycle period in M+1 cycle periods, Dᵢ_{_{threshold}} represents the target threshold of the differentiation component D of the i-th cycle period, represents the first adaptive parameter of the differentiation component D of the i-th cycle period, βᵢ_{ₐ₃} represents the second adaptive parameter of the differentiation component D of the i-th cycle period, and t represents the duration of the cycle period.

According to a third aspect of the embodiments of the present disclosure, there is provided a device for controlling constant-diameter growth of monocrystalline silicon, wherein the device for controlling constant-diameter growth of monocrystalline silicon comprises a processor and a memory, the memory stores at least one computer instruction, and the computer instruction is loaded and executed by the processor to implement the steps of the method for controlling constant-diameter growth of monocrystalline silicon described by the first aspect and any one of the embodiments of the first aspect.

According to a fourth aspect of the embodiments of the present disclosure, there is provided a computer-readable storage medium, wherein the storage medium stores at least one computer instruction, and the computer instruction is loaded and executed by a processor to implement the steps of the method for controlling constant-diameter growth of monocrystalline silicon described by the first aspect and any one of the embodiments of the first aspect.

It should be understood that the above general description and the following detailed description are merely exemplary and explanatory, and cannot limit the present disclosure.

### BRIEF DESCRIPTION OF THE DRAWINGS

In order to more clearly illustrate the technical solutions of the embodiments of the present application or the prior art, the figures that are required to describe the embodiments or the prior art will be briefly introduced below. Apparently, the figures that are described below are embodiments of the present application, and a person skilled in the art can obtain other figures according to these figures without paying creative work.

The drawings here are incorporated into the description and form part of the description. The drawings show the embodiments of the present disclosure, and interpret the principle of the present disclosure together with the description.

FIG. 1 is a flow chart of the method for controlling constant-diameter growth of monocrystalline silicon according to an embodiment of the present disclosure;

FIG. 2 is curves of the variations of the crystal-pulling-rate fluctuation amplitude and the crystal-diameter deviation with the crystal constant-diameter length according to an embodiment of the present disclosure, wherein the PID values are not corrected;

FIG. 3 is curves of the variations of the crystal-pulling-rate fluctuation amplitude and the crystal-diameter deviation with the crystal constant-diameter length according to an embodiment of the present disclosure, wherein the PID values have been corrected;

FIG. 4 is a structural diagram of the apparatus for controlling constant-diameter growth of monocrystalline silicon according to an embodiment of the present disclosure;

FIG. 5 is a structural diagram of the apparatus for controlling constant-diameter growth of monocrystalline silicon according to an embodiment of the present disclosure;

FIG. 6 is a structural diagram of the apparatus for controlling constant-diameter growth of monocrystalline silicon according to an embodiment of the present disclosure; and

FIG. 7 is a structural diagram of the device for controlling constant-diameter growth of monocrystalline silicon according to an embodiment of the present disclosure.

### DETAILED DESCRIPTION

In order to make one of the objects, the technical solutions and the advantages of the embodiments of the present application clearer, the technical solutions of the embodiments of the present application will be clearly and completely described below with reference to the drawings of the embodiments of the present application. Apparently, the described embodiments are merely certain embodiments of the present application, rather than all of the embodiments. All of the other embodiments that a person skilled in the art obtains on the basis of the embodiments of the present application without paying creative work fall within the protection scope of the present application.

Here the exemplary embodiments are in detail described, the examples of which are illustrated in the drawings. Where the description below involves the drawings, unless otherwise indicated, the same numbers in different figures denote the same or similar elements. The implementations described in the following exemplary embodiments do not represent all of the embodiments of the present disclosure. In contrast, they are merely examples of the devices and the methods according to some aspects of the present disclosure as described in detail in the attached claims.

An embodiment of the present disclosure provides a method for controlling constant-diameter growth of monocrystalline silicon. As shown in FIG. 1, the method for controlling constant-diameter growth of monocrystalline silicon comprises the steps of:

101: acquiring PID initial values of an i-th cycle period.

In an embodiment of the present disclosure, the step of acquiring the PID initial values of the i-th cycle period comprises: determining PID corrected values of an (i−1)-th cycle period to be the PID initial values of the i-th cycle period. In other words, the PID initial values of the current cycle period are the PID corrected values of the previous one cycle period. The PID initial values include an initial value of a proportion component P, an initial value of an integration component I and an initial value of a differentiation component D, and i≥1.

Exemplarily, when i=1, the PID initial values of the first cycle period are P₀, I₀ and D₀. Generally, the P₀, I₀ and D₀ are determined according to empiric values. In physical production process, the PID initial values are determined according to the deviation of the actual crystal growth diameter from the target crystal diameter. When 1=2, the PID initial values of the second cycle period are the PID corrected values of the first cycle period, i.e., P₁_{_{corrected}}, I₁_{_{corrected}}, and D₁_{_{corrected}}. When i=3, the PID initial values of the third cycle period are the PID corrected values of the second cycle period, i.e., P₂_{_{corrected}}, I₂_{_{corrected}} and D₂_{_{corrected}}. The rest can be done in the same manner. When i=N, the PID initial values of the N-th cycle period are the PID corrected values of the (N−1)-th cycle period, i.e., P_{(N-1)corrected}, I_{(N-1)corrected} and D_{(N-1)corrected}. When 1=N+1, the PID initial values of the (N+1)-th cycle period are the PID corrected values of the N-th cycle period, i.e., P_{N}_{_{corrected}}, I_{N}_{_{corrected}} and D_{N}_{_{corrected}}.

102: correcting the PID initial values of the i-th cycle period, and obtaining PID corrected values of the i-th cycle period.

In an embodiment of the present disclosure, the PID corrected values include a corrected value of the proportion component P, a corrected value of the integration component I and a corrected value of the differentiation component D.

By referring to the description of the step 101, when i=1, the corrected values corresponding to the initial values of the P value, the I value and the D value P₀, I₀ and D₀ are P₁_{_{corrected}}, I₁_{_{corrected}} and D₁_{_{corrected}}.When i=2, the initial values of the P value, the I value and the D value are P₁_{_{corrected}}, I₁_{_{corrected}} and D₁_{_{corrected}}, and the corresponding corrected values are P₂_{_{corrected}}, I₂_{_{corrected}} and D₂_{_{corrected}}. When 1=3, the initial values of the P value, the I value and the D value are P₂_{_{corrected}}, I₂_{_{corrected}} and D₂_{_{corrected}}, and the corresponding corrected values are P₃_{_{corrected}}, I₃_{_{corrected}} and D₃_{_{corrected}} . The rest can be done in the same manner. When i=N, the initial values of the P value, the I value and the D value are P_{(N-1)corrected}, I_{(N-1)corrected} and D_{(N-1)corrected}, and the corresponding corrected values are P_{N}_{_{corrected}}, I_{N}_{_{corrected}} and D_{N}_{_{corrected}}.

Particularly, the step 102 comprises the following steps:

S1: setting, in the i-th cycle period, a target threshold of the proportion component P and a corresponding adaptive parameter, a target threshold of the integration component I and a corresponding adaptive parameter and a target threshold of the differentiation component D and a corresponding adaptive parameter.

Sequentially particularly described below are the setting of the target threshold of the proportion component P and the corresponding adaptive parameter, the target threshold of the integration component I and the corresponding adaptive parameter and the target threshold of the differentiation component D and the corresponding adaptive parameter.

Firstly, the step of setting the target threshold of the proportion component P of the i-th cycle period and the corresponding adaptive parameter comprises:

acquiring a diameter difference of the i-th cycle period;

setting 1/100-½ of an absolute value of the diameter difference of the i-th cycle period to be the target threshold of the proportion component P;

setting 1/1000- 1/10000 of the initial value of the proportion component P of the i-th cycle period to be a first adaptive parameter of the proportion component P; and

setting 1/10000- 1/100000 of the initial value of the proportion component P of the i-th cycle period to be a second adaptive parameter of the proportion component P.

the step of acquiring the diameter difference of the i-th cycle period comprises: collecting an initial crystal diameter of the i-th cycle period, wherein the initial crystal diameter is the actual diameter of the crystal growth; and setting the target crystal diameter of the i-th cycle period, and then calculating to obtain the diameter difference between the target crystal diameter and the initial crystal diameter of the i-th cycle period. Because the diameter difference between the target crystal diameter and the initial crystal diameter may have a negative value, in the embodiments of the present disclosure, when the diameter difference is processed, all of the diameter differences are required to obtain the absolute values. Further, 1/100-½ of the absolute value of the diameter difference of the i-th cycle period is set to be the target threshold of the proportion component P of the i-th cycle period. The adaptive parameter of the proportion component P of the i-th cycle period is determined according to the initial value of the proportion component P of the i-th cycle period.

Secondly, the step of setting the target threshold of the integration component I of the i-th cycle period and the corresponding adaptive parameter comprises:

acquiring diameter differences of the i-th cycle period and M cycle periods preceding the i-th cycle period;

calculating an average value of all of the diameter differences of the M+1 cycle periods;

setting 1/100-½ of the average value to be the target threshold of the integration component I;

determining 1/1000- 1/10000 of the initial value of the integration component I of the i-th cycle period to be a first adaptive parameter of the integration component I; and

determining 1/10000- 1/100000 of the initial value of the integration component I of the i-th cycle period to be a second adaptive parameter of the integration component I.

It should be noted that the M herein refers to the quantity of the selected cycle periods, M≤i−1. Therefore, when M=i−1, that means acquiring the diameter differences of all of the cycle periods preceding the i-th cycle period. When M<i−1, that means acquiring the diameter differences of M cycle periods that are neighboring the i-th cycle period and are successive. The size of M may be selected according to the actual condition.

The mode of acquiring the diameter difference of the i-th cycle period may refer to the step of acquiring the diameter difference of the i-th cycle period when setting the target threshold of the proportion component P, and is not discussed here further. Because the M cycle periods preceding the i-th cycle period have already completed the controlling on the crystal diameter, the process may comprise acquiring the diameter differences of the M cycle periods preceding the i-th cycle period from history data; then, solving the average value of the absolute values of all of the diameter differences of the M+1 cycle periods; and in turn, setting 1/100-½ of the average value to be the target threshold of the integration component I. The adaptive parameter of the integration component I of the i-th cycle period is determined according to the initial value of the integration component I of the i-th cycle period.

Thirdly, setting the target threshold of the differentiation component D of the i-th cycle period and the corresponding adaptive parameter comprises:

acquiring the diameter differences of each of the M cycle periods preceding the i-th cycle period;

calculating a standard deviation of all of the diameter differences of the M+1 cycle periods;

setting 1/100-½ of the standard deviation to be the target threshold of the differentiation component D;

determining 1/1000- 1/10000 of the initial value of the differentiation component D of the i-th cycle period to be a first adaptive parameter of the differentiation component D; and

determining 1/10000- 1/100000 of the initial value of the differentiation component D of the i-th cycle period to be a second adaptive parameter of the differentiation component

D.

It should be noted that the M cycle periods here are the same as the above M cycle periods in the setting of the target threshold of the integration component I. Therefore, the process comprises, according to the absolute values of all of the diameter differences of the M+1 cycle periods and the average value of the absolute values of all of the diameter differences of the M+1 cycle periods, calculating to obtain the standard deviation of the absolute values of all of the diameter differences of the M+1 cycle periods, and setting 1/100-½ of the standard deviation to be the target threshold of the differentiation component D. The adaptive parameter of the differentiation component D of the i-th cycle period is determined according to the initial value of the differentiation component D of the i-th cycle period.

S2: according to the target threshold of the proportion component P and the corresponding adaptive parameter, calculating to obtain the corrected value of the proportion component P.

Particularly, the step S2 comprises: according to the diameter difference of the i-th cycle period and the target threshold of the proportion component P of the i-th cycle period and the corresponding adaptive parameter, by using a first formula, calculating to obtain the corrected value of the proportion component P of the i-th cycle period, wherein the first formula comprises:

Pᵢ_{_{corrected}}=P₍ᵢ₋₁₎_{_{corrected}}+(|Dᵢ_{ₑᵣᵣ}|−Pᵢ_{_{threshold}})×αᵢ_{ₐ₁}+∫₀^{t}(|Dᵢ_{ₑᵣᵣ}|−Pᵢ_{_{threshold}})×βᵢ_{ₐ₁}

wherein Pᵢ_{_{corrected}} represents the corrected value of the proportion component P of the i-th cycle period, P₍ᵢ₋₁₎_{_{corrected}} represents the initial value of the proportion component P of the i-th cycle period, Dᵢ_{ₑᵣᵣ} represents the diameter difference of the i-th cycle period, |Dᵢ_{ₑᵣᵣ}| represents the absolute value of the diameter difference of the i-th cycle period, αᵢ_{ₐ₁} represents the first adaptive parameter of the proportion component P of the i-th cycle period, βᵢ_{ₐ₁} represents the second adaptive parameter of the proportion component P of the i-th cycle period, Pᵢ_{_{threshold}} represents the target threshold of the proportion component P of the i-th cycle period, and t represents the duration of the cycle period.

S3: according to the target threshold of the integration component I and the corresponding adaptive parameter, calculating to obtain the corrected value of the integration component I.

Particularly, the step S3 comprises: according to the diameter difference of the i-th cycle period, the diameter differences of the M cycle periods preceding the i-th cycle period and the target threshold of the integration component I of the i-th cycle period and the corresponding adaptive parameter, by using a second formula, calculating to obtain the corrected value of the integration component I of the i-th cycle period, wherein the second formula comprises:

Iᵢ_{_{corrected}}=I₍ᵢ₋₁₎_{_{corrected}}+(|̅D̅ⱼ̅_̅{̅ₑ̅ᵣ̅ᵣ̅}̅|̅−Iᵢ_{_{threshold}})×αᵢ_{ₐ₂}+∫₀^{t}(|̅D̅ⱼ̅_̅{̅ₑ̅ᵣ̅ᵣ̅}̅|̅−Iᵢ_{_{threshold}})×βᵢ_{ₐ₂}

wherein Iᵢ_{_{correctd}} represents the corrected value of the integration component I of the i-th cycle period, I₍ᵢ₋₁₎_{_{corrected}} represents the initial value of the integration component I of the i-th cycle period, Dⱼ_{ₑᵣᵣ} represents the diameter difference of the i-th cycle period in M+1 cycle periods, |D̅ⱼ̅_̅{̅ₑ̅ᵣ̅ᵣ̅}̅| represents the average value of the absolute values of all of the diameter differences in the M+1 cycle periods, M represents the quantity of the cycle periods, αᵢ_{ₐ₂} represents the first adaptive parameter of the integration component I of the i-th cycle period, βᵢ_{ₐ₂} represents the second adaptive parameter of the integration component I of the i-th cycle period, Iᵢ_{_{threshold}} represents the target threshold of the integration component I of the i-th cycle period, and t represents the duration of the cycle period.

S4: according to the target threshold of the differentiation component D and the corresponding adaptive parameter, calculating to obtain the corrected value of the differentiation component D.

Particularly, the step S4 comprises: according to the diameter difference of the i-th cycle period, the diameter differences of the M cycle periods preceding the i-th cycle period, the initial value of the differentiation component D of the i-th cycle period and the target threshold of the differentiation component D of the i-th cycle period and the corresponding adaptive parameter, by using a third formula, calculating to obtain the corrected value of the differentiation component D, wherein the third formula comprises:

$${D}_{{i}_{corrected}} = {D}_{{( i - 1 )}_{corrected}} + ( \sqrt{\frac{1}{M + 1} \sum {( \vert {D}_{{j}_{err}} \vert )}^{2}} - {D}_{{i}_{threshold}} ) \times {α}_{{i}_{a 3}} + {\int }_{0}^{t} ( \sqrt{\frac{1}{M + 1} \sum {( \vert {D}_{{j}_{err}} \vert )}^{2}} - {D}_{{i}_{threshold}} ) \times {β}_{{i}_{a 3}}$$

wherein Dᵢ_{_{corrected}} represents the corrected value of the differentiation component D of the i-th cycle period, D₍ᵢ₋₁₎_{_{corrected}} represents the initial value of the differentiation component D of the i-th cycle period, Dⱼ_{ₑᵣᵣ} represents the diameter difference of the j-th cycle period in M cycle periods, Dᵢ_{_{threshold}} represents the target threshold of the differentiation component D of the i-th cycle period, αᵢ_{ₐ₃} represents the first adaptive parameter of the differentiation component D of the i-th cycle period, βᵢ_{ₐ₃} represents the second adaptive parameter of the differentiation component D of the i-th cycle period, and t represents the duration of the cycle period.

103: according to the PID corrected values of the i-th cycle period, controlling a crystal growth diameter of the i-th cycle period.

After the PID corrected values of the i-th cycle period have been obtained, the PID controlling method is used to control the crystal growth of the i-th cycle period. Particularly, the PID controlling method may be used to control the crystal growth speed, and in turn control the crystal growth diameter, and the PID controlling method may also be used to control the crystal growth temperature, and in turn control the crystal growth diameter.

The method for controlling constant-diameter growth of monocrystalline silicon according to the embodiments of the present disclosure acquires PID initial values of an i-th cycle period; corrects the PID initial values of the i-th cycle period, and obtains PID corrected values of the i-th cycle period; and according to the PID corrected values of the i-th cycle period, controls a crystal growth diameter of the i-th cycle period. The method, by correcting in real time the PID values of each of the cycle periods in the process of the crystal constant-diameter growth, automatically adjusts the controlling level of the crystal constant-diameter growth, to in turn control the crystal diameter better.

On the basis of the method for controlling constant-diameter growth of monocrystalline silicon according to the above embodiment corresponding to FIG. 1, another embodiment of the present disclosure provides a method for controlling constant-diameter growth of monocrystalline silicon. The method for controlling constant-diameter growth of monocrystalline silicon according to the present embodiment employs the PID controlling method, by automatically correcting the PID parameter values in the cycle periods by using a single-crystal-furnace controlling system, to in turn control the crystal diameter. The method comprises mainly the steps of: firstly, setting the initial values corresponding to the P value, the I value and the D value; then, setting the target thresholds corresponding to the P value, the I value and the D value and the adaptive parameters corresponding to the P value, the I value and the D value, correcting the initial values, and outputting the corrected values; and, finally, by using the corrected values corresponding to the P value, the I value and the D value, controlling the crystal diameter by using the PID controlling method. The above steps will be particularly described below.

The first step: setting the initial values.

The present embodiment comprises performing the circulation with t as the duration of the cycle periods, within the i-th cycle period, setting the initial values of the P value, the I value and the D value to be respectively P₍ᵢ₋₁₎_{_{corrected}}, I₍ᵢ₋₁₎_{_{corrected}} and D₍ᵢ₋₁₎_{_{corrected}}, and calculating out that the corrected values corresponding to the initial values P₍ᵢ₋₁₎_{_{corrected}}, I₍ᵢ₋₁₎_{_{corrected}} and D₍ᵢ₋₁₎_{_{corrected}} and Pᵢ_{_{corrected}}, Iᵢ_{_{corrected}} and Dᵢ_{_{corrected}}.

Exemplarily, when i=1, the initial values P₍ᵢ₋₁₎_{_{corrected}}, I₍ᵢ₋₁₎_{_{corrected}} and D₍ᵢ₋₁₎_{_{corrected}} of the P value, the I value and the D value are respectively P₀, I₀ and D₀, and it is calculated out that the corrected values corresponding to the initial values P₀, I₀ and D₀ are P₁_{_{corrected}}, I₁_{_{corrected}} and D₁_{_{corrected}}.

When i=2, the initial values of the P value, the I value and the D value are P₁_{_{corrected}}, I₁_{_{corrected}} and D₁_{_{corrected}}, and it is calculated out that the corrected values corresponding to the initial values P₁_{_{corrected}}, I₁_{_{corrected}} and D₁_{_{corrected}} are P₂_{_{corrected}}, I₂_{_{corrected}} and D₂_{_{corrected}}.

When i=3, the initial values of the P value, the I value and the D value are P₂_{_{corrected}}, I₂_{_{corrected}} and D₂_{_{corrected}}, and it is calculated out that the corrected values corresponding to the initial values P₂_{_{corrected}}, I₂_{_{corrected}} and D₂_{_{corrected}} are P₃_{_{corrected}}, I₃_{_{corrected}} and D₃_{_{corrected}}.

The rest can be done in the same manner. It is calculated out that the corrected values of the N-th cycle period are P_{N}_{_{corrected}}, I_{N}_{_{corrected}} and D_{N}_{_{corrected}}.

The initial values P₀, I₀ and D₀ are determined empirically. In physical production process, the PID initial values are determined according to the deviation of the actual crystal growth diameter from the target crystal diameter.

The second step: correcting the initial values.

The particular process of the correction of the corrected values corresponding to the initial values mainly comprises: setting the target thresholds of the P value, the I value and the D value and the adaptive parameters corresponding to the P value, the I value and the D value; and correcting the initial values of the P value, the I value and the D value, and outputting the corrected values. The process particularly comprises:

Step 1: within the i-th cycle period, setting a target crystal diameter, and calculating out the difference between a system-fed-back diameter from the controlling system and the target crystal diameter; and acquiring the diameter differences of the M cycle periods preceding the i-th cycle period.

Step 2: setting the target thresholds corresponding to the P value, the I value and the D value Pᵢ_{_{threshold}}, Iᵢ_{_{threshold}} and Dᵢ_{_{threshold}} and the adaptive parameters corresponding to the P value, the I value and the D value, and the setting methods are respectively as follows:

a. setting the target threshold of the P value Pᵢ_{_{threshold}}, and the adaptive parameters corresponding to the P value

The target threshold Pᵢ_{_{threshold}}: within the i-th cycle period, the target threshold Pᵢ_{_{threshold}} is set to be 1/100 to ½ of the absolute value of the Dᵢ_{ₑᵣᵣ}.

The adaptive parameters corresponding to the P value include: αᵢ_{ₐ₁} and βᵢ_{ₐ₁}, wherein the αᵢ_{ₐ₁} is set to be 1/1000 to 1/10000 of the P₍ᵢ₋₁₎_{_{corrected}}, and the βᵢ_{ₐ₁} is set to be 1/10000 to 1/100000 of the P₍ᵢ₋₁₎_{_{corrected}}.

b. setting the target threshold of the I value Iᵢ_{_{threshold}}, and the adaptive parameters corresponding to the I value

The target threshold Iᵢ_{_{threshold}}: within the i-th cycle period, the target threshold Iᵢ_{_{threshold}} is set to be 1/100 to ½ of the average value of the absolute values of the Dᵢ_{ₑᵣᵣ}, wherein the average value of the absolute values of the Dᵢ_{ₑᵣᵣ} described here refers to the average value of the absolute values of the diameter differences of the M+1 cycle periods, i.e., the average value of the absolute value of the diameter difference of the i-th cycle period and the absolute values of the diameter differences of the M cycle periods preceding the i-th cycle period.

The adaptive parameters corresponding to the I value include: αᵢ_{ₐ₂} and βᵢ_{ₐ₂}, wherein the αᵢ_{ₐ₂} is set to be 1/1000 to 1/10000 of the I₍ᵢ₋₁₎_{_{corrected}}, and the βᵢ_{ₐ₂} is set to be 1/10000 to 1/100000 of the I₍ᵢ₋₁₎_{_{corrected}}.

c. setting the target threshold of the D value Dᵢ_{_{threshold}}, and the adaptive parameters corresponding to the D value

The target threshold Dᵢ_{_{threshold}}: within the i-th cycle period, the target threshold Dᵢ_{_{threshold}} is set to be 1/100 to ½ of the standard deviation of the absolute values of the Dᵢ_{ₑᵣᵣ}, wherein the standard deviation of the absolute values of the Dᵢ_{ₑᵣᵣ} described here refers to the standard deviation of the absolute values of the diameter differences of the M+1 cycle periods, i.e., the standard deviation of the absolute value of the diameter difference of the i-th cycle period and the absolute values of the diameter differences of the M cycle periods preceding the i-th cycle period.

The adaptive parameters corresponding to the D value include: αᵢ_{ₐ₃} and βᵢ_{ₐ₃}, wherein the αᵢ_{ₐ₃} is set to be 1/1000 to 1/10000 of the D₍ᵢ₋₁₎_{_{corrected}}, and the βᵢ_{ₐ₃} is set to be 1/10000 to 1/100000 of the D₍ᵢ₋₁₎_{_{corrected}}.

Step 3: within the i-th cycle period, calculating the corrected values corresponding to the initial values of the P value, the I value and the D value Pᵢ_{_{corrected}}, Iᵢ_{_{corrected}} and Dᵢ_{_{corrected}}, wherein the calculating methods are respectively as follows:

a. calculating the corresponding corrected value of the initial value of the P value, by using the calculating formula (2):

Pᵢ_{_{corrected}}=P₍ᵢ₋₁₎_{_{corrected}}+(|Dᵢ_{ₑᵣᵣ}|−Pᵢ_{_{threshold}})×αᵢ_{ₐ₁}+∫₀^{t}(|Dᵢ_{ₑᵣᵣ}|−Pᵢ_{_{threshold}})×βᵢ_{ₐ₁}

b. calculating the corresponding corrected value of the initial value of the I value, by using the calculating formula (3):

Iᵢ_{_{corrected}}=I₍ᵢ₋₁₎_{_{corrected}}+(|̅D̅ⱼ̅_̅{̅ₑ̅ᵣ̅ᵣ̅}̅|̅−Iᵢ_{_{threshold}})×αᵢ_{ₐ₂}+∫₀^{t}(|̅D̅ⱼ̅_̅{̅ₑ̅ᵣ̅ᵣ̅}̅|̅−Iᵢ_{_{threshold}})×βᵢ_{ₐ₂}

c. calculating the corresponding corrected value of the initial value of the D value, by using the calculating formula (4):

$${D}_{{i}_{corrected}} = {D}_{{( i - 1 )}_{corrected}} + ( \sqrt{\frac{1}{M + 1} \sum {( \vert {D}_{{j}_{err}} \vert )}^{2}} - {D}_{{i}_{threshold}} ) \times {α}_{{i}_{a 3}} + {\int }_{0}^{t} ( \sqrt{\frac{1}{M + 1} \sum {( \vert {D}_{{j}_{err}} \vert )}^{2}} - {D}_{{i}_{threshold}} ) \times {β}_{{i}_{a 3}}$$

The meanings of the symbols in the formulas (2)-(4) may refer to the description on the corresponding formulas in the embodiment corresponding to FIG. 1, and is not discussed here further.

The description will be made by using i=N, i.e., the N-th cycle period, as the example.

Within the N-th cycle period, the absolute value of the diameter difference D_{N}_{ₑᵣᵣ} between the system-fed-back diameter and the target crystal diameter is 0.6, and accordingly the target threshold P_{N}_{_{threshold}} may be set to be in the range of 0.3-0.006. If the initial value of the P value P_{(N-1)corrected} is 3, the value range of α_{N}_{ₐ₁} may be 0.003-0.0003, and the value range of β_{N}_{ₐ₁} may be 0.0003-0.00003.

Within the N-th cycle period, the average value of the absolute values of all of the diameter differences from the first cycle period to the N-th cycle period is 0.4, and accordingly the value range of the target threshold I_{N}_{_{threshold}} may be 0.2-0.004. If the initial value of the I value I_{(N-1)corrected} is 0.05, the value range of α_{N}_{ₐ₂} may be 0.00005-0.000005, and the value range of β_{N}_{ₐ₂} may be 0.000005-0.0000005.

Within the N-th cycle period, the standard deviation of the absolute values of all of the diameter differences from the first cycle period to the N-th cycle period is 0.04, and accordingly the value range of the target threshold D_{N}_{_{threshold}} may be 0.02-0.0004. If the initial value of the D value D_{(N-1)corrected} is 600, the value range of α_{N}_{ₐ₃} may be 0.6-0.06, and the value range of β_{N}_{ₐ₃} may be 0.06-0.006.

Particularly, within the N-th cycle period, it is set that the initial value of the P value P_{(N-1)corrected}=3, P_{N}_{_{corrected}}=0.01, α_{N}_{ₐ₁}=0.003 and β_{N}_{ₐ₁}=0.0005, and the absolute value of the deviation of the crystal diameter within the period is 0.6 mm.

According to the formula (2), it is obtained that P_{N}_{_{corrected}}=3+(0.6−0.1)*0.003+0.5*0.0005=3.00175. Therefore, within the (N+1)-th cycle period, the initial value of the P value is set to be P_{N}_{_{corrected}}=3.00175. Within the (N+1)-th cycle period, it is calculated out that the absolute value of the diameter deviation D_{(N+1)}_{ₑᵣᵣ} is 0.05 mm, and accordingly it is set that P₍ₙ₊₁₎_{_{threshold}}=0.005, α_{(N+1)}_{ₐ₁}=0.003 and β_{(N+1)}_{ₐ₁}=0.005. According to the formula (2), it can be obtained that, within the (N+1)-th cycle period P_{(N+1)}_{_{corrected}}=3.00175+(0.05−0.005)*0.003+0.045*0.0005=3.0019075. Accordingly, P_{(N+2)}_{_{corrected}} is calculated according to the corrected value of the (N+1)-th cycle period P_{(N+1)}_{_{corrected}}, and then the circulated calculation is performed.

In the same manner, within the N-th cycle period, the initial value and the target threshold I_{N}_{_{threshold}} of the I value and the adaptive parameters corresponding to the I value α_{N}_{ₐ₂} and β_{N}_{ₐ₂} are set, and the corrected value corresponding to the initial value of the I value I_{N}_{_{corrected}} is calculated out. Within the (N+1)-th cycle period, the initial value of the I value is set to be I_{N}_{_{corrected}}, the corrected value I_{(N+1)corrected} is calculated, and then the circulated calculation is performed.

In the same manner, within the N-th cycle period, the initial value D_{(N-1)corrected} and the target threshold D_{N}_{_{threshold}} of the D value and the adaptive parameters corresponding to the D value α_{N}_{ₐ₃} and β_{N}_{ₐ₃} are set, and the corrected value corresponding to the initial value of the D value D is calculated out. Within the (N+1)-th cycle period, the initial value of the D value is set to be D_{N}_{_{corrected}}, the corrected value D_{(N+1)corrected} is calculated, and then the circulated calculation is performed.

The third step: diameter controlling.

Within the N-th cycle period, according to the P_{N}_{_{corrected}}, the I_{N}_{_{corrected}} and the D_{N}_{_{corrected}} calculated out in the second step, by using the PID controlling method, the crystal diameter within the N-th cycle period is controlled. Particularly, the PID controlling method may be used to control the crystal growth speed, and in turn control the crystal growth diameter, and certainly, the PID controlling method may also be used to control the crystal growth temperature, and in turn control the crystal growth diameter.

Taking controlling the crystal growth speed by using the PID controlling method as the example, in the actual process of crystal constant-diameter growth, by regulating the crystal growth speed, the deviation of the crystal growth diameter is controlled. Because, according to the influence on the crystal growth speed by the PID parameter values, suitable initial values are set, and in turn the initial values are corrected to control the crystal growth. The calculation principle of controlling the crystal growth speed by using the PID controlling method is as follows:

$$V = {V}_{0} + Δ Di * P + {{\int }_{0}}^{t 1} Δ Di * I + \frac{dDi}{dt} * D$$

wherein V₀ represents the initial speed of crystal growth, V represents the crystal growth speed, ΔDi represents the deviation between the actual crystal growth diameter and the target crystal growth diameter, Di represents the crystal growth diameter, and t1 represents the crystal growth duration.

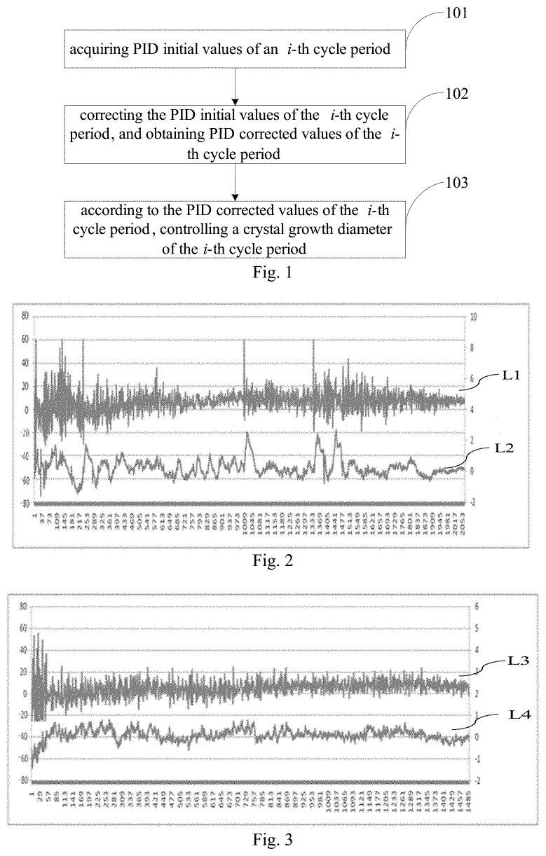

As shown in FIGS. 2 and 3, FIG. 2 is curves of the variations of the crystal-pulling-rate fluctuation amplitude and the crystal-diameter deviation with the crystal constant-diameter length during the process of the controlling of the crystal growth by using the PID controlling method, wherein the P value, the I value and the D value are not corrected. L1 represents the fluctuation amplitude of the actual crystal pulling rate, L2 represents the difference between the actual crystal diameter and the target crystal diameter, the number axis on the left of FIG. 2 represents the value of the fluctuation amplitude of the crystal pulling rate, the number axis on the right represents the diameter difference, and the horizontal coordinate represents the constant-diameter length of the crystal. It can be known from FIG. 2 that the fluctuation amplitude of the crystal pulling rate is not constant, wherein the fluctuation amplitude is from −30 mm/h to +60 mm/h, and the amplitude reaches 90 mm/h, and the range of the fluctuation of the diameter difference is ±2 mm.

FIG. 3 is curves of the variations of the crystal-pulling-rate fluctuation amplitude and the crystal-diameter deviation with the crystal constant-diameter length during the process of the controlling of the crystal growth by using the PID controlling method, wherein the P value, the I value and the D value have been corrected. L3 represents the fluctuation amplitude of the actual crystal pulling rate, L4 represents the difference between the actual crystal diameter and the target crystal diameter, the number axis on the left of FIG. 3 represents the value of the fluctuation amplitude of the crystal pulling rate, the number axis on the right represents the diameter difference, and the horizontal coordinate represents the constant-diameter length of the crystal. It can be known from FIG. 3 that, after 50 mm of constant-diameter growth, the fluctuation amplitude of the pulling rate is maintained at −15 mm/h to +20 mm/h, the amplitude is approximately 35 mm/h, and the range of the fluctuation of the diameter is ±1 mm.

By comparing the fluctuation amplitudes of the crystal pulling rate and the diameter deviations in FIG. 2 and FIG. 3, it can be known that, by self-adaptively correcting the PID parameter values, the controlling level of the crystal diameter can be automatically adjusted, thereby controlling the crystal pulling rate and controlling the crystal diameter better.

The method for controlling constant-diameter growth of monocrystalline silicon according to the embodiments of the present disclosure acquires PID initial values of an i-th cycle period, wherein i≥1; corrects the PID initial values of the i-th cycle period, and obtains PID corrected values of the i-th cycle period; and according to the PID corrected values of the i-th cycle period, controls a crystal growth diameter of the i-th cycle period. The method, by correcting in real time the PID values of each of the cycle periods in the process of the crystal constant-diameter growth, automatically adjusts the controlling level of the crystal constant-diameter growth, to in turn control the crystal diameter better.

On the basis of the method for controlling constant-diameter growth of monocrystalline silicon described in the above embodiment corresponding to FIG. 1, the apparatus embodiments of the present disclosure are provided below, and may be used to implement the process embodiments of the present disclosure.

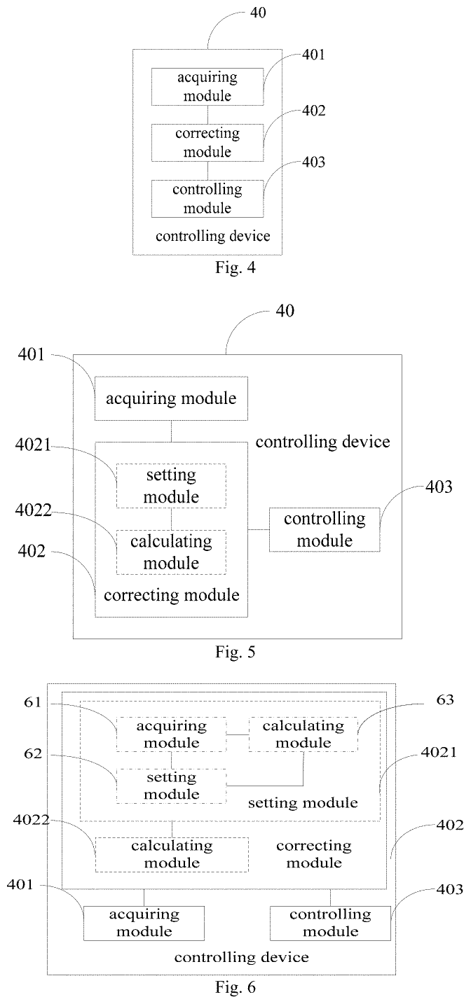

An embodiment of the present disclosure provides an apparatus for controlling constant-diameter growth of monocrystalline silicon. As shown in FIG. 4, the controlling apparatus 40 comprises: an acquiring module 401, a correcting module 402 and a controlling module 403;

the acquiring module 401 is configured for acquiring PID initial values of an i-th cycle period, wherein the PID initial values include an initial value of a proportion component P, an initial value of an integration component I and an initial value of a differentiation component D, and i≥1;

the correcting module 402 is configured for correcting the PID initial values of the i-th cycle period, and obtaining PID corrected values of the i-th cycle period, wherein the PID corrected values include a corrected value of the proportion component P, a corrected value of the integration component I and a corrected value of the differentiation component D; and

the controlling module 403 is configured for, according to the PID corrected values of the i-th cycle period, controlling a crystal growth diameter of the i-th cycle period.

In an embodiment, the acquiring module 401 is configured for determining PID corrected values of an (i−1)-th cycle period to be the PID initial values of the i-th cycle period.

In an embodiment, as shown in FIG. 5, the correcting module 402 comprises: a setting module 4021 and a calculating module 4022;

the setting module 4021 is configured for setting, in the i-th cycle period, a target threshold of the proportion component P and a corresponding adaptive parameter, a target threshold of the integration component I and a corresponding adaptive parameter and a target threshold of the differentiation component D and a corresponding adaptive parameter;

the calculating module 4022 is configured for, according to the target threshold of the proportion component P and the corresponding adaptive parameter, calculating to obtain the corrected value of the proportion component P;

the calculating module 4022 is configured for, according to the target threshold of the integration component I and the corresponding adaptive parameter, calculating to obtain the corrected value of the integration component I; and

the calculating module 4022 is configured for, according to the target threshold of the differentiation component D and the corresponding adaptive parameter, calculating to obtain the corrected value of the differentiation component D.

As shown in FIG. 6, the setting module 4021 comprises: an acquiring module 61, a setting module 62 and a calculating module 63.

In an embodiment, the acquiring module 61 is configured for acquiring a diameter difference of the i-th cycle period;

the setting module 62 is configured for setting 1/100-½ of an absolute value of the diameter difference of the i-th cycle period to be the target threshold of the proportion component P;

the setting module 62 is configured for setting 1/1000- 1/10000 of the initial value of the proportion component P of the i-th cycle period to be a first adaptive parameter of the proportion component P; and

the setting module 62 is configured for setting 1/10000- 1/100000 of the initial value of the proportion component P of the i-th cycle period to be a second adaptive parameter of the proportion component P.

In an embodiment, the acquiring module 61 is configured for acquiring diameter differences of the i-th cycle period and M cycle periods preceding the i-th cycle period, wherein M≤i−1;

the calculating module 63 is configured for calculating an average value of all of the diameter differences of the M+1 cycle periods;

the setting module 62 is configured for setting 1/100-½ of the average value to be the target threshold of the integration component I;

the setting module 62 is configured for setting 1/1000- 1/10000 of the initial value of the integration component I of the i-th cycle period to be a first adaptive parameter of the integration component I; and

the setting module 62 is configured for setting 1/10000- 1/100000 of the initial value of the integration component I of the i-th cycle period to be a second adaptive parameter of the integration component I.

In an embodiment, the acquiring module 61 is configured for acquiring diameter differences of the i-th cycle period and M cycle periods preceding the i-th cycle period, wherein M≤i−1;

the calculating module 63 is configured for calculating a standard deviation of all of the diameter differences of the M+1 cycle periods;

the setting module 62 is configured for setting 1/100-½ of the standard deviation to be the target threshold of the differentiation component D;

the setting module 62 is configured for setting 1/1000- 1/10000 of the initial value of the differentiation component D of the i-th cycle period to be a first adaptive parameter of the differentiation component D; and

the setting module 62 is configured for setting 1/10000- 1/100000 of the initial value of the differentiation component D of the i-th cycle period to be a second adaptive parameter of the differentiation component D.

In an embodiment, the calculating module 4022 is configured for, according to the diameter difference of the i-th cycle period and the target threshold of the proportion component P and the corresponding adaptive parameter, by using a first formula, calculating to obtain the corrected value of the proportion component P, wherein the first formula comprises:

Pᵢ_{_{corrected}}=P₍ᵢ₋₁₎_{_{corrected}}+(|Dᵢ_{ₑᵣᵣ}|−Pᵢ_{_{threshold}})×αᵢ_{ₐ₁}+∫₀^{t}(|Dᵢ_{ₑᵣᵣ}|−Pᵢ_{_{threshold}})×βᵢ_{ₐ₁}

wherein Pᵢ_{_{corrected}} represents the corrected value of the proportion component P of the i-th cycle period, P₍ᵢ₋₁₎_{_{corrected}} represents the initial value of the proportion component P of the i-th cycle period, Dᵢ_{ₑᵣᵣ} represents the diameter difference of the i-th cycle period, αᵢ_{ₐ₁} represents the first adaptive parameter of the proportion component P, βᵢ_{ₐ₁} represents the second adaptive parameter of the proportion component P, Pᵢ_{_{threshold}} represents the target threshold of the proportion component P of the i-th cycle period, and t represents the duration of the cycle period.

In an embodiment, the calculating module 4022 is configured for, according to the diameter difference and the target threshold of the integration component I and the corresponding adaptive parameter, by using a second formula, calculating to obtain the corrected value of the integration component I, wherein the second formula comprises:

Iᵢ_{_{corrected}}=I₍ᵢ₋₁₎_{_{corrected}}+(|̅D̅ⱼ̅_̅{̅ₑ̅ᵣ̅ᵣ̅}̅|̅−Iᵢ_{_{threshold}})×αᵢ_{ₐ₂}+∫₀^{t}(|̅D̅ⱼ̅_̅{̅ₑ̅ᵣ̅ᵣ̅}̅|̅−Iᵢ_{_{threshold}})×βᵢ_{ₐ₂}

wherein Iᵢ_{_{corrected}} represents the corrected value of the integration component I of the i-th cycle period, I₍ᵢ₋₁₎_{_{corrected}} represents the initial value of the integration component I of the i-th cycle period, Dⱼ_{ₑᵣᵣ} represents the diameter difference of the i-th cycle period in M+1 cycle periods, |D̅ⱼ̅_̅{̅ₑ̅ᵣ̅ᵣ̅}̅| represents the average value of the absolute values of all of the diameter differences in the M+1 cycle periods, αᵢ_{ₐ₂} represents the first adaptive parameter of the integration component I of the i-th cycle period, βᵢ_{ₐ₂} represents the second adaptive parameter of the integration component I of the i-th cycle period, Iᵢ_{_{threshold}} represents the target threshold of the integration component I of the i-th cycle period, and t represents the duration of the cycle period.

In an embodiment, the calculating module 4022 is configured for, according to the diameter difference and the target threshold of the differentiation component D and the corresponding adaptive parameter, by using a third formula, calculating to obtain the corrected value of the differentiation component D, wherein the third formula comprises:

$${D}_{{i}_{corrected}} = {D}_{{( i - 1 )}_{corrected}} + ( \sqrt{\frac{1}{M + 1} \sum {( \vert {D}_{{j}_{err}} \vert )}^{2}} - {D}_{{i}_{threshold}} ) \times {α}_{{i}_{a 3}} + {\int }_{0}^{t} ( \sqrt{\frac{1}{M + 1} \sum {( \vert {D}_{{j}_{err}} \vert )}^{2}} - {D}_{{i}_{threshold}} ) \times {β}_{{i}_{a 3}}$$

wherein Dᵢ_{_{corrected}} represents the corrected value of the differentiation component D of the i-th cycle period, D₍ᵢ₋₁₎_{_{corrected}} represents the initial value of the differentiation component D of the i-th cycle period, Dⱼ_{ₑᵣᵣ} represents the diameter difference of the i-th cycle period in M+1 cycle periods, Dᵢ_{_{threshold}} represents the target threshold of the differentiation component D of the i-th cycle period, αᵢ_{ₐ₃} represents the first adaptive parameter of the differentiation component D of the i-th cycle period, βᵢ_{ₐ₃} represents the second adaptive parameter of the differentiation component D of the i-th cycle period, and t represents the duration of the cycle period.

The apparatus for controlling constant-diameter growth of monocrystalline silicon according to the embodiments of the present disclosure acquires PID initial values of an i-th cycle period, wherein i≥1; corrects the PID initial values of the i-th cycle period, and obtains PID corrected values of the i-th cycle period; and according to the PID corrected values of the i-th cycle period, controls a crystal growth diameter of the i-th cycle period. The method, by correcting in real time the PID values of each of the cycle periods in the process of the crystal constant-diameter growth, automatically adjusts the controlling level of the crystal constant-diameter growth, to in turn control the crystal diameter better.

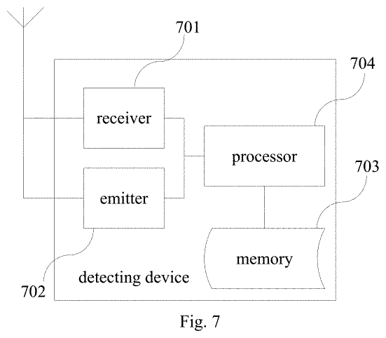

As shown in FIG. 7, an embodiment of the present disclosure further provides a device for controlling constant-diameter growth of monocrystalline silicon, wherein the device for controlling constant-diameter growth of monocrystalline silicon comprises a receiver 701, a transmitter 702, a memory 703 and a processor 704, the transmitter 702 and the memory 703 are connected to the processor 704, the memory 703 stores at least one computer instruction, and the processor 704 is configured to load and execute the at least one computer instruction, to implement the method for controlling constant-diameter growth of monocrystalline silicon described in the above embodiment corresponding to FIG. 1.

On the basis of the method for controlling constant-diameter growth of monocrystalline silicon described in the above embodiment corresponding to FIG. 1, an embodiment of the present disclosure further provides a computer-readable storage medium. For example, the non-transitory computer-readable storage medium may be a Read Only Memory (ROM), a Random Access Memory (RAM), a CD-ROM, a magnetic tape, a floppy disk, an optical data storage device and so on. The storage medium stores at least one computer instruction, to implement the method for controlling constant-diameter growth of monocrystalline silicon described in the above embodiment corresponding to FIG. 1.

A person skilled in the art can understand that all or some of the steps for implementing the above embodiments may be completed by hardware, and may also be completed by using a program to instruct relevant hardware. The program may be stored in a computer-readable storage medium. The above-mentioned storage medium may be a read only memory, a magnetic disk, an optical disk and so on.

A person skilled in the art, after considering the description and implementing the contents disclosure herein, will readily envisage other embodiments of the present disclosure. The present disclosure aims at encompassing any variations, uses or adaptative alternations of the present disclosure, wherein those variations, uses or adaptative alternations follow the general principle of the present disclosure and include common knowledge or common technical means in the art that are not disclosed by the present disclosure. The description and the embodiments are merely deemed as exemplary, and the true scope and spirit of the present disclosure are presented by the following claims.

Finally, it should be noted that the above embodiments are merely intended to explain the technical solutions of the present application, and not to limit them. Although the present application is explained in detail by referring to the above embodiments, a person skilled in the art should understand that he can still modify the technical solutions set forth by the above embodiments, or make equivalent substitutions to part of the technical features of them. However, those modifications or substitutions do not make the essence of the corresponding technical solutions depart from the spirit and scope of the technical solutions of the embodiments of the present application.

1. A method for controlling constant-diameter growth of monocrystalline silicon, wherein the method comprises:
acquiring PID initial values of an i-th cycle period, wherein the PID initial values include an initial value of a proportion component P, an initial value of an integration component I and an initial value of a differentiation component D, and i≥1;
correcting the PID initial values of the i-th cycle period, and obtaining PID corrected values of the i-th cycle period, wherein the PID corrected values include a corrected value of the proportion component P, a corrected value of the integration component I and a corrected value of the differentiation component D; and
according to the PID corrected values of the i-th cycle period, controlling a crystal growth diameter of the i-th cycle period.

2. The method according to claim 1, wherein the step of acquiring the PID initial values of the i-th cycle period comprises:
determining PID corrected values of an (i−1)-th cycle period to be the PID initial values of the i-th cycle period.

3. The method according to claim 1, wherein the step of correcting the PID initial values of the i-th cycle period, and obtaining the PID corrected values of the i-th cycle period comprises:
setting, in the i-th cycle period, a target threshold of the proportion component P and a corresponding adaptive parameter, a target threshold of the integration component I and a corresponding adaptive parameter and a target threshold of the differentiation component D and a corresponding adaptive parameter;
according to the target threshold of the proportion component P and the corresponding adaptive parameter, calculating to obtain the corrected value of the proportion component P;
according to the target threshold of the integration component I and the corresponding adaptive parameter, calculating to obtain the corrected value of the integration component I; and
according to the target threshold of the differentiation component D and the corresponding adaptive parameter, calculating to obtain the corrected value of the differentiation component D.

4. The method according to claim 3, wherein the step of setting the target threshold of the proportion component P of the i-th cycle period and the corresponding adaptive parameter comprises:
acquiring a diameter difference of the i-th cycle period, wherein the diameter difference is a difference between a target crystal diameter and a real-time crystal diameter;
setting 1/100-½ of an absolute value of the diameter difference of the i-th cycle period to be the target threshold of the proportion component P;
setting 1/1000- 1/10000 of the initial value of the proportion component P of the i-th cycle period to be a first adaptive parameter of the proportion component P; and
setting 1/10000- 1/100000 of the initial value of the proportion component P of the i-th cycle period to be a second adaptive parameter of the proportion component P.

5. The method according to claim 4, wherein the step of, according to the target threshold of the proportion component P and the corresponding adaptive parameter, calculating to obtain the corrected value of the proportion component P comprises:
according to the diameter difference of the i-th cycle period and the target threshold of the proportion component P and the corresponding adaptive parameter, by using a first formula, calculating to obtain the corrected value of the proportion component P, wherein the first formula comprises:
Pᵢ_{_{corrected}}=P₍ᵢ₋₁₎_{_{corrected}}+(|Dᵢ_{ₑᵣᵣ}|−Pᵢ_{_{threshold}})×αᵢ_{ₐ₁}+∫₀^{t}(|Dᵢ_{ₑᵣᵣ}|−Pᵢ_{_{threshold}})×βᵢ_{ₐ₁}
wherein Pᵢ_{_{corrected}} represents the corrected value of the proportion component P of the i-th cycle period, P₍ᵢ₋₁₎_{_{corrected}} represents the initial value of the proportion component P of the i-th cycle period, Dᵢ_{ₑᵣᵣ} represents the diameter difference of the i-th cycle period, αᵢ_{ₐ₁} represents the first adaptive parameter of the proportion component P, βᵢ_{ₐ₁} represents the second adaptive parameter of the proportion component P, Pᵢ_{_{threshold}} represents the target threshold of the proportion component P of the i-th cycle period, and t represents the duration of the cycle period.

6. The method according to claim 4, wherein the step of acquiring the diameter difference of the i-th cycle period comprises:
collecting an initial crystal diameter of the i-th cycle period;
setting the target crystal diameter of the i-th cycle period; and
according to the crystal growth diameter of the i-th cycle period and the target crystal diameter of the i-th cycle period, calculating to obtain the diameter difference of the i-th cycle period.

7. The method according to claim 3, wherein the step of setting the target threshold of the integration component I of the i-th cycle period and the corresponding adaptive parameter comprises:
acquiring diameter differences of the i-th cycle period and M cycle periods preceding the i-th cycle period, wherein M≤i−1;
calculating an average value of all of the diameter differences of the M+1 cycle periods;
setting 1/100-½ of the average value to be the target threshold of the integration component I;
setting 1/1000- 1/10000 of the initial value of the integration component I of the i-th cycle period to be a first adaptive parameter of the integration component I; and
setting 1/10000- 1/100000 of the initial value of the integration component I of the i-th cycle period to be a second adaptive parameter of the integration component I.

8. The method according to claim 7, wherein the step of, according to the diameter difference and the target threshold of the integration component I and the corresponding adaptive parameter, calculating to obtain the corrected value of the integration component I comprises:
according to the diameter difference and the target threshold of the integration component I and the corresponding adaptive parameter, by using a second formula, calculating to obtain the corrected value of the integration component I, wherein the second formula comprises:
Iᵢ_{_{corrected}}=I₍ᵢ₋₁₎_{_{corrected}}+(|̅D̅ⱼ̅_̅{̅ₑ̅ᵣ̅ᵣ̅}̅|̅−Iᵢ_{_{threshold}})×αᵢ_{ₐ₂}+∫₀^{t}(|̅D̅ⱼ̅_̅{̅ₑ̅ᵣ̅ᵣ̅}̅|̅−Iᵢ_{_{threshold}})×βᵢ_{ₐ₂}
wherein Iᵢ_{_{corrected}} represents the corrected value of the integration component I of the i-th cycle period, I₍ᵢ₋₁₎_{_{corrected}} represents the initial value of the integration component I of the i-th cycle period, Dⱼ_{ₑᵣᵣ} represents the diameter difference of the i-th cycle period in M+1 cycle periods, |D̅ⱼ̅_̅{̅ₑ̅ᵣ̅ᵣ̅}̅| represents the average value of the absolute values of all of the diameter differences in the M+1 cycle periods, α₁_{ₐ₂} represents the first adaptive parameter of the integration component I, βᵢ_{ₐ₂} represents the second adaptive parameter of the integration component I, Iᵢ_{_{threshold}} represents the target threshold of the integration component I of the i-th cycle period, and t represents the duration of the cycle period.

9. The method according to claim 3, wherein the step of setting the target threshold of the differentiation component D of the i-th cycle period and the corresponding adaptive parameter comprises:
acquiring diameter differences of the i-th cycle period and M cycle periods preceding the i-th cycle period, wherein M≤i−1;
calculating a standard deviation of all of the diameter differences of the M+1 cycle periods;
setting 1/100-½ of the standard deviation to be the target threshold of the differentiation component D;
setting 1/1000- 1/10000 of the initial value of the differentiation component D of the i-th cycle period to be a first adaptive parameter of the differentiation component D; and
setting 1/10000- 1/100000 of the initial value of the differentiation component D of the i-th cycle period to be a second adaptive parameter of the differentiation component D.

10. The method according to claim 9, wherein the step of, according to the target threshold of the differentiation component D and the corresponding adaptive parameter, calculating to obtain the corrected value of the differentiation component D comprises:
according to the diameter difference and the target threshold of the differentiation component D and the corresponding adaptive parameter, by using a third formula, calculating to obtain the corrected value of the differentiation component D, wherein the third formula comprises:
$${D}_{{i}_{corrected}} = {D}_{{( i - 1 )}_{corrected}} + ( \sqrt{\frac{1}{M + 1} \sum {( \vert {D}_{{j}_{err}} \vert )}^{2}} - {D}_{{i}_{threshold}} ) \times {α}_{{i}_{a 3}} + {\int }_{0}^{t} ( \sqrt{\frac{1}{M + 1} \sum {( \vert {D}_{{j}_{err}} \vert )}^{2}} - {D}_{{i}_{threshold}} ) \times {β}_{{i}_{a 3}}$$
wherein Dᵢ_{_{corrected}} represents the corrected value of the differentiation component D of the i-th cycle period, D₍ᵢ₋₁₎_{_{corrected}} represents the initial value of the differentiation component D of the i-th cycle period, Dⱼ_{ₑᵣᵣ} represents the diameter difference of the i-th cycle period in M+1 cycle periods, Dᵢ_{_{threshold}} represents the target threshold of the differentiation component D of the i-th cycle period, αᵢ_{ₐ₃} represents the first adaptive parameter of the differentiation component D, βᵢ_{ₐ₃} represents the second adaptive parameter of the differentiation component D, and t represents the duration of the cycle period.

11. A device for controlling constant-diameter growth of monocrystalline silicon, wherein the device for controlling constant-diameter growth of monocrystalline silicon comprises a processor and a memory, the memory stores at least one computer instruction, and the computer instruction is loaded and executed by the processor to implement the steps of:
acquiring PID initial values of an i-th cycle period, wherein the PID initial values include an initial value of a proportion component P, an initial value of an integration component I and an initial value of a differentiation component D, and i≥1;
correcting the PID initial values of the i-th cycle period, and obtaining PID corrected values of the i-th cycle period, wherein the PID corrected values include a corrected value of the proportion component P, a corrected value of the integration component I and a corrected value of the differentiation component D; and
according to the PID corrected values of the i-th cycle period, controlling a crystal growth diameter of the i-th cycle period.

12. A computer-readable storage medium, wherein the storage medium stores at least one computer instruction, and the computer instruction is loaded and executed by a processor to implement the steps of:
acquiring PID initial values of an i-th cycle period, wherein the PID initial values include an initial value of a proportion component P, an initial value of an integration component I and an initial value of a differentiation component D, and i≥1;
correcting the PID initial values of the i-th cycle period, and obtaining PID corrected values of the i-th cycle period, wherein the PID corrected values include a corrected value of the proportion component P, a corrected value of the integration component I and a corrected value of the differentiation component D; and
according to the PID corrected values of the i-th cycle period, controlling a crystal growth diameter of the i-th cycle period.

13. The device according to claim 11, wherein the step of acquiring the PID initial values of the i-th cycle period comprises:
determining PID corrected values of an (i−1)-th cycle period to be the PID initial values of the i-th cycle period.

14. The device according to claim 11, wherein the step of correcting the PID initial values of the i-th cycle period, and obtaining the PID corrected values of the i-th cycle period comprises:
setting, in the i-th cycle period, a target threshold of the proportion component P and a corresponding adaptive parameter, a target threshold of the integration component I and a corresponding adaptive parameter and a target threshold of the differentiation component D and a corresponding adaptive parameter;
according to the target threshold of the proportion component P and the corresponding adaptive parameter, calculating to obtain the corrected value of the proportion component P;
according to the target threshold of the integration component I and the corresponding adaptive parameter, calculating to obtain the corrected value of the integration component I; and
according to the target threshold of the differentiation component D and the corresponding adaptive parameter, calculating to obtain the corrected value of the differentiation component D.

15. The device according to claim 14, wherein the step of setting the target threshold of the proportion component P of the i-th cycle period and the corresponding adaptive parameter comprises:
acquiring a diameter difference of the i-th cycle period, wherein the diameter difference is a difference between a target crystal diameter and a real-time crystal diameter;
setting 1/100-½ of an absolute value of the diameter difference of the i-th cycle period to be the target threshold of the proportion component P;
setting 1/1000- 1/10000 of the initial value of the proportion component P of the i-th cycle period to be a first adaptive parameter of the proportion component P; and
setting 1/10000- 1/100000 of the initial value of the proportion component P of the i-th cycle period to be a second adaptive parameter of the proportion component P.

16. The device according to claim 14, wherein the step of, according to the target threshold of the proportion component P and the corresponding adaptive parameter, calculating to obtain the corrected value of the proportion component P comprises:
according to the diameter difference of the i-th cycle period and the target threshold of the proportion component P and the corresponding adaptive parameter, by using a first formula, calculating to obtain the corrected value of the proportion component P, wherein the first formula comprises:
Pᵢ_{_{corrected}}=P₍ᵢ₋₁₎_{_{corrected}}+(|Dᵢ_{ₑᵣᵣ}|−Pᵢ_{_{threshold}})×αᵢ_{ₐ₁}+∫₀^{t}(|Dᵢ_{ₑᵣᵣ}|−Pᵢ_{_{threshold}})×βᵢ_{ₐ₁}
wherein Pᵢ_{_{corrected}} represents the corrected value of the proportion component P of the i-th cycle period, P₍ᵢ₋₁₎_{_{corrected}} represents the initial value of the proportion component P of the i-th cycle period, Dᵢ_{ₑᵣᵣ} represents the diameter difference of the i-th cycle period, αᵢ_{ₐ₁} represents the first adaptive parameter of the proportion component P, βᵢ_{ₐ₁} represents the second adaptive parameter of the proportion component 1³, Pᵢ_{_{threshold}} represents the target threshold of the proportion component P of the i-th cycle period, and t represents the duration of the cycle period.

17. The device according to claim 15, wherein the step of acquiring the diameter difference of the i-th cycle period comprises:
collecting an initial crystal diameter of the i-th cycle period;
setting the target crystal diameter of the i-th cycle period; and
according to the crystal growth diameter of the i-th cycle period and the target crystal diameter of the i-th cycle period, calculating to obtain the diameter difference of the i-th cycle period.

18. The device according to claim 14, wherein the step of setting the target threshold of the integration component I of the i-th cycle period and the corresponding adaptive parameter comprises:
acquiring diameter differences of the i-th cycle period and M cycle periods preceding the i-th cycle period, wherein M≤i−1;
calculating an average value of all of the diameter differences of the M+1 cycle periods;
setting 1/100-½ of the average value to be the target threshold of the integration component I;
setting 1/1000- 1/10000 of the initial value of the integration component I of the i-th cycle period to be a first adaptive parameter of the integration component I; and
setting 1/10000- 1/100000 of the initial value of the integration component I of the i-th cycle period to be a second adaptive parameter of the integration component I.

19. The device according to claim 14, wherein the step of, according to the diameter difference and the target threshold of the integration component I and the corresponding adaptive parameter, calculating to obtain the corrected value of the integration component I comprises:
according to the diameter difference and the target threshold of the integration component I and the corresponding adaptive parameter, by using a second formula, calculating to obtain the corrected value of the integration component I, wherein the second formula comprises:
Iᵢ_{_{corrected}}=I₍ᵢ₋₁₎_{_{corrected}}+(|̅D̅ⱼ̅_̅{̅ₑ̅ᵣ̅ᵣ̅}̅|̅−Iᵢ_{_{threshold}})×αᵢ_{ₐ₂}+∫₀^{t}(|̅D̅ⱼ̅_̅{̅ₑ̅ᵣ̅ᵣ̅}̅|̅−Iᵢ_{_{threshold}})×βᵢ_{ₐ₂}
wherein Iᵢ_{_{corrected}} represents the corrected value of the integration component I of the i-th cycle period, I₍ᵢ₋₁₎_{_{corrected}} represents the initial value of the integration component I of the i-th cycle period, Dⱼ_{ₑᵣᵣ} represents the diameter difference of the i-th cycle period in M+1 cycle periods, |D̅ⱼ̅_̅{̅ₑ̅ᵣ̅ᵣ̅}̅| represents the average value of the absolute values of all of the diameter differences in the M+1 cycle periods, αᵢ_{ₐ₂} represents the first adaptive parameter of the integration component I, βᵢ_{ₐ₂} represents the second adaptive parameter of the integration component I, Iᵢ_{_{threshold}} represents the target threshold of the integration component I of the i-th cycle period, and t represents the duration of the cycle period.

20. The device according to claim 14, wherein the step of setting the target threshold of the differentiation component D of the i-th cycle period and the corresponding adaptive parameter comprises:
acquiring diameter differences of the i-th cycle period and M cycle periods preceding the i-th cycle period, wherein M≤i−1;
calculating a standard deviation of all of the diameter differences of the M+1 cycle periods;
setting 1/100-½ of the standard deviation to be the target threshold of the differentiation component D;
setting 1/1000- 1/10000 of the initial value of the differentiation component D of the i-th cycle period to be a first adaptive parameter of the differentiation component D; and
setting 1/10000- 1/100000 of the initial value of the differentiation component D of the i-th cycle period to be a second adaptive parameter of the differentiation component D.
